(19) United States
(12) Patent Application Publication
(10) Pub. No.: US 2005/0161078 A1
(43) Pub. Date: Jul. 28, 2005

(54) Solar cell mechanical interconnection using direct wafer bonding

(76) Inventor: Daniel Aiken, Cedar Crest, NM (US)

Correspondence Address: WHITE & CASE LLP;PATENT DEPARTMENT, 1155 AVENUE OF THE AMERICAS, NEW YORK, NY, 10036, US

(21) Appl. No.: 10/765,532

(22) Filed: Jan. 27, 2004

(51) Int. Cl. H01L 31/00

(52) U.S. Cl. 136/259; 136/255

(57) ABSTRACT

A multi-junction solar cell includes a plurality of monolithic cells joined together by direct wafer bonds. Each monolithic cell has at least one junction. The direct wafer bonds include no intervening material between joined monolithic cells. The direct wafer bonds are achieved by bonding forces between dipoles at the surfaces of adjoining monolithic cells.

### GOVERNMENT LICENSE RIGHTS

The U.S. Government has a paid-up license in this invention and the right in limited circumstances to require the patent owner to license others on reasonable terms as provided for by the terms of contract NAS3-02201 awarded by NASA.

### FIELD OF THE INVENTION

This invention relates generally to solar cell technology and relates more particularly to solar cell mechanical interconnection using direct wafer bonding.

### BACKGROUND

Solar cells are an increasingly important source of electrical power, particularly for space-based applications such as satellites. Increasing the efficiency of solar cells is an important goal for designers and manufacturers of solar cell products. Increasing the efficiency of solar cells can be achieved with multi-junction solar cells in which the bandgaps of the constituent cells are tuned to better match the solar spectrum. For example, in a multi-junction solar cell composed of three constituent cells, each constituent cell is tuned to a different portion of the solar spectrum by selection of the materials used for each constituent cell.

However, high-quality multi-junction solar cells with optimum bandgap combinations cannot be epitaxially grown with lattice matching on a single substrate. A technique for overcoming this materials limitation is to produce monolithic single-junction solar cells and mechanically stack them to produce a multi-junction cell. Monolithic single-junction cells can be produced on different substrates to create a greater number of possible bandgap combinations. The single-junction cells are then mechanically stacked to optimally tune the bandgaps to the solar spectrum.

FIG. 1 is a block diagram of a prior art embodiment of a multi-junction solar cell 100. Cell 100 includes two single-junction constituent cells 112, 116 and an interconnect structure 114. Interconnect structure 114 is a mechanical interconnect structure that is typically implemented as a metal grid and an anti-reflective coating. Interconnect structure 114 provides electrical conductivity and optical transparency between cell 112 and cell 116. However, a conventional interconnect structure such as interconnect structure 114 incurs optical losses due to reflection at the interface due to poor index matching and absorption at the metal grid lines. Interconnect structure 114 also incurs thermal management problems due to poor thermal conductivity across the structure. Cell 100 is also complex to produce because the process requires multiple grid metallizations, photolithography steps, and anti-reflective coating applications.

Interconnect structure 114 may also be implemented as a thin layer of metal. This layer of metal must be thin enough to be optically transparent to the appropriate wavelengths of light yet still provide electrical conductivity between cell 112 and cell 116. In this embodiment, cell 100 is produced by coating the top of cell 116 with a metal, which becomes interconnect structure 114, and then placing cell 112 on top of the metal. Cell 100 is then heated and cell 112 and cell 116 are compressed together for a period of time. This type of interconnect structure 114 may be referred to as “wafer bonding” and is further described in P. R. Sharps et al., “Wafer Bonding for Use in Mechanically Stacked Multi-Bandgap Cells,” proceedings IEEE PVSC, p. 895, 1997.

FIG. 2 is a block diagram of a prior art embodiment of a partially processed multi-junction solar cell 200. Cell 200 is based on a low cost, mechanically robust substrate layer 218, which is typically made from silicon. A material for a transferred layer 216 is then implanted with hydrogen ions. The ion-implanted material of transferred layer 216 is bonded to substrate layer 218 using slight pressure at room temperature and then annealed to initiate hydrogen-induced layer exfoliation and layer transfer. The material of transferred layer 216 is selected to match the lattice constant of the material intended for a p-type epitaxially-grown layer 214, which is grown onto transferred layer 216. An n-type epitaxially-grown layer 212 is then added to cell 200, producing a junction 220.

This technique uses transferred layer 216 as an epitaxial template for the growth of layers having lattice constants that do not match the lattice constant of substrate layer 218. This technique is further described in J. M. Zahler et al., “Wafer Bonding and Layer Transfer Processes for 4-Junction High Efficiency Solar Cells,” Proceeding IEEE PVSC, p. 1039, 2002.

### SUMMARY

A multi-junction solar cell includes a plurality of monolithic cells joined together by direct wafer bonds. Each monolithic cell has at least one junction and is preferably grown on a separate substrate. The direct wafer bonds include no intervening material between joined monolithic cells. Each direct wafer bond electrically, optically, and thermally connects two adjacent monolithic cells with low losses.

The surfaces of the monolithic cells are joined at room temperature without the use of outside forces to form the direct wafer bonds. The surfaces of the monolithic cells are joined without the use of glue or any other type of adhesive. The direct wafer bonds are achieved by bonding forces between dipoles at the surfaces of adjoining monolithic cells.

### BRIEF DESCRIPTION OF THE DRAWINGS

FIG. 1 is a block diagram of a prior art embodiment of a multi-junction solar cell;

FIG. 2 is a block diagram of a prior art embodiment of a partially processed multi-junction solar cell;

FIG. 3 is a block diagram of one embodiment of a multi-junction solar cell, in accordance with the invention; and

FIG. 4 is a flowchart of method steps for producing a multi-junction solar cell using direct wafer bonding, in accordance with one embodiment of the invention.

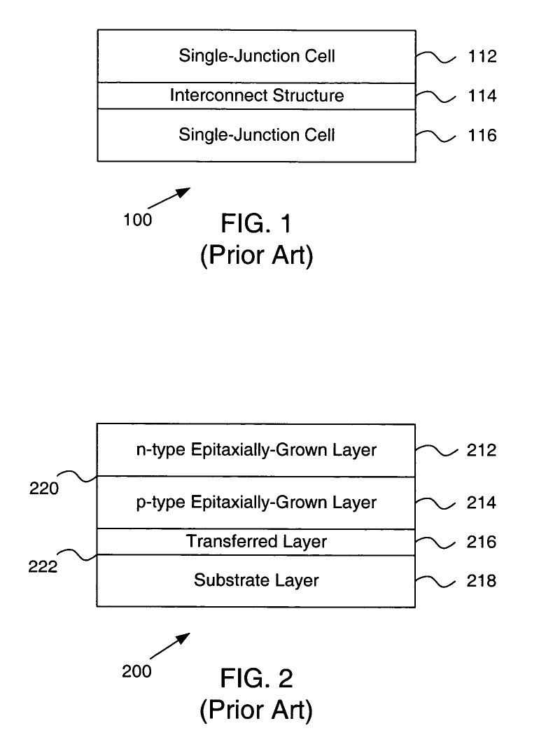

### DETAILED DESCRIPTION OF THE DRAWINGS

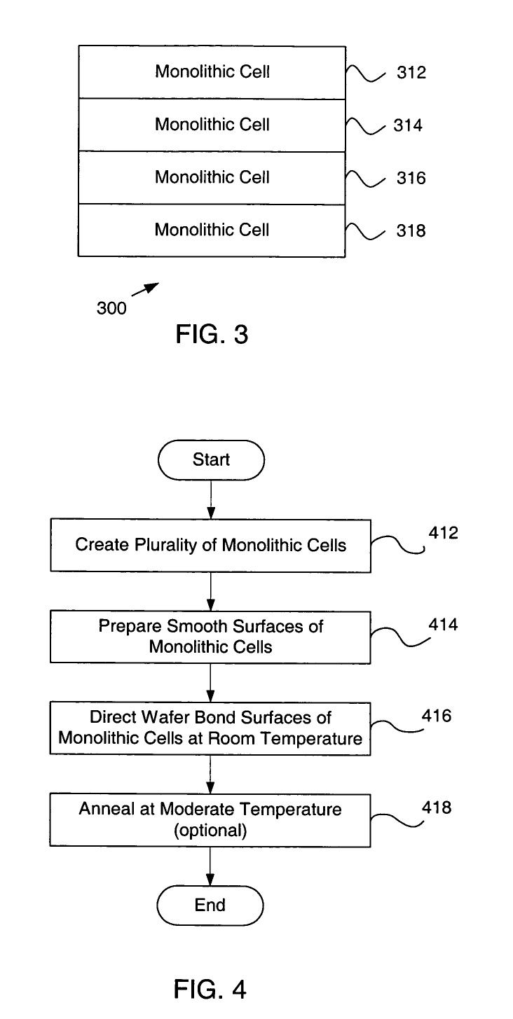

FIG. 3 is a block diagram of one embodiment of a multi-junction solar cell 300, in accordance with the invention. Cell 300 includes a plurality of constituent cells, specifically four monolithic cells 312, 314, 316, and 318. Although cell 300 is shown as having four constituent cells, any multi-junction cell having two or more constituent cells is within the scope of the invention. Each of these monolithic cells was produced separately (grown on separate substrates) and include at least one p-n junction. Monolithic cells having more than one p-n junction are within the scope of the invention. The materials of monolithic cells 312, 314, 316, and 318 are not required to have matching lattice constants. The materials used for each of monolithic cells 312, 314, 316, and 318 were selected according to the desired bandgap of each cell.

Monolithic cell 316 and monolithic cell 318 are held together by a direct wafer bond. There is no intervening material between monolithic cell 316 and monolithic cell 318. The top surface of monolithic cell 318 and the bottom surface of monolithic cell 316 are very smooth and flat. The bottom surface of monolithic cell 316 and the top surface of monolithic cell 318 were joined without outside forces and without using any type of glue or other adhesive. In the direct wafer bond, monolithic cell 316 and monolithic cell 318 are held together by bonding forces between dipoles at the smooth bottom surface of monolithic cell 316 and the smooth top surface of monolithic cell 318. Such bonding forces may include, but are not limited to, Van der Waals forces and hydrogen bonding forces.

Monolithic cell 316 is direct wafer bonded to monolithic cell 314, which in turn is direct wafer bonded to monolithic cell 312. There is no intervening material between any of the constituent cells of cell 300. The direct wafer bonds of cell 300 electrically, optically, and thermally connect the constituent cells of cell 300. The direct wafer bonds have low electrical loss, are transparent, and are mechanically stable. Cell 300 thus does not experience the performance loss problems of cells having metal grid or other types of metallic interconnect structures. Assembling cell 300 with direct wafer bonding is a simple and inexpensive process that only requires that the surfaces of monolithic cells 312, 314, 316, and 318 are smooth.

FIG. 4 is a flowchart of method steps for producing a multi-junction solar cell, in accordance with one embodiment of the invention. In step 412, a plurality of monolithic cells are created. Each cell is grown on a separate substrate and has at least one junction. Each of the monolithic cells has a bandgap that covers a different part of the solar spectrum than the other monolithic cells. In step 414, the appropriate surfaces of each monolithic cell are smoothed using any appropriate techniques known in the art. In step 416, the surfaces of the monolithic cells are direct wafer bonded at room temperature. The surfaces of the monolithic cells are joined together with no outside forces and are held together by bonding forces between dipoles at the surfaces of the monolithic cells. In optional step 418, the multi-junction cell is annealed at a moderate temperature, e.g. 300-400° C., to strengthen the bonds between the monolithic cells.

Although FIG. 4 shows direct wafer bonding at room temperature, direct wafer bonding of monolithic cells at higher or lower temperatures is within the scope of the invention.

The invention has been described above with reference to specific embodiments. It will, however, be evident that various modifications and changes may be made thereto without departing from the broader spirit and scope of the invention as set forth in the appended claims. The foregoing description and drawings are, accordingly, to be regarded in an illustrative rather than a restrictive sense.

1. A multi-junction solar cell, comprising:
a plurality of monolithic cells, each monolithic cell including at least one junction,
each of the monolithic cells being bonded to at least one other of the monolithic cells with a direct wafer bond, wherein the direct wafer bond does not include any intervening material between the monolithic cells.

2. The multi-junction solar cell of claim 1, wherein the direct wafer bond in achieved by bonding forces between dipoles at a surface of a first one of the monolithic cells and a surface of a second one of the monolithic cells.

3. The multi-junction solar cell of claim 1, wherein each of the plurality of monolithic cells has a bandgap that is different from the bandgaps of the other monolithic cells.

4. The multi-junction solar cell of claim 1, wherein the multi-junction solar cell has been annealed to strengthen the direct wafer bonds between the plurality of monolithic cells.

5. The multi-junction solar cell of claim 1, wherein the multi-junction solar cell includes four junctions.

6. The multi-junction solar cell of claim 1, wherein at least one of the plurality of monolithic cells includes more than one junction.

7. The multi-junction solar cell of claim 1, wherein each of the plurality of monolithic cells was epitaxially grown on separate substrates.

8. The multi-junction solar cell of claim 1, wherein each of the plurality of monolithic cells has a lattice constant that is different than the lattice constants of the other monolithic cells.

9. A multi-junction solar cell comprising:
a plurality of constituent cells, each constituent cell including at least one junction,
the plurality of constituent cells being joined by direct wafer bonds.

10. The multi-junction solar cell of claim 9, wherein each of the constituent cells is joined to at least one other of the constituent cells by a direct wafer bond, wherein the direct wafer bond includes no intervening material between the joined constituent cells.

11. The multi-junction solar cell of claim 9, wherein each of the plurality of constituent cells is a monolithic cell epitaxially grown on a separate substrate.

12. The multi-junction solar cell of claim 9, wherein the direct wafer bonds are achieved by bonding forces between surfaces of adjoining constituent cells.

13. The multi-junction solar cell of claim 9, wherein at least one of the plurality of constituent cells includes more than one junction.

14. A method for producing a multi-junction solar cell, comprising:
providing a plurality of monolithic cells, each monolithic cell having at least one junction; and
joining together the plurality of monolithic cells with direct wafer bonds.

15. The method of claim 14, further comprising:
smoothing at least one surface of each monolithic cell prior to joining.

16. The method of claim 14, wherein each of the direct wafer bonds does not include any intervening material between surfaces of adjacent monolithic cells.

17. The method of claim 14, wherein each of the direct wafer bonds is achieved by bonding forces between dipoles at a surface of one of the monolithic cells and a surface of another of the monolithic cells.

18. The method of claim 14, wherein at least one of the plurality of monolithic cells includes more than one junction.

19. The method of claim 14, further comprising:
annealing the multi-junction solar cell to strengthen the direct wafer bonds.

20. The method of claim 14, wherein each of the plurality of monolithic cells has a bandgap that is different from the bandgaps of the other monolithic cells.
